(19) United States
(12) Patent Application Publication
(10) Pub. No.: US 2026/0191043 A1
(43) Pub. Date: Jul. 2, 2026

(54) SOLID STATE DEVICE INCLUDING A STITCH PORTION BETWEEN DIFFERENT DIES AND METHODS OF FORMING THE SAME

(71) Applicant: PsiQuantum, Corp., Palo Alto, CA (US)

(72) Inventors: Nicholas V. LiCausi, Watervliet, NY (US); Erik R. HOSLER, Thompsontown, PA (US)

(21) Appl. No.: 19/131,874

(22) PCT Filed: Nov. 16, 2023
(86) PCT No.: PCT/US2023/080175

§ 371 Date: May 21, 2025

Related U.S. Application Data
(60) Provisional application No. 63/384,699, filed on Nov. 22, 2022.

(51) Int. Cl. H10W 70/60; G02B 6/12; G02B 6/13; H10W 70/08; H10W 90/10

(52) U.S. Cl. CPC H10W 70/616; G02B 6/12004; G02B 6/13; H10W 70/08; H10W 90/10

(57) ABSTRACT

A solid state device includes a substrate, a first die on the substrate and having a first sidewall, a second die different than the first die on the substrate and having a second sidewall facing the first sidewall, and a first stitch portion connecting the first die at the first sidewall to the second die at the second sidewall.

### FIELD

The present invention relates to solid state devices, and particularly to a photolithography method in which a stitch portion is located between different solid state device dies.

### BACKGROUND

There are currently several methods being used to achieve multi-part integration in solid state devices. Such methods may include, for example, die-to-wafer bonding and wafer-to-wafer bonding. However, these methods may not provide satisfactory results in some cases. In particular, for photonic integrated circuits (photonic ICs) there may be a high optical loss penalty when transitioning between different substrates/interposers/chips.

### SUMMARY

According to an aspect of the present disclosure, a solid state device may include a substrate, a first die on the substrate and having a first sidewall, a second die different than the first die on the substrate and having a second sidewall facing the first sidewall, and a first stitch portion connecting the first die at the first sidewall to the second die at the second sidewall.

According to another aspect of the present disclosure, a method of forming a solid state device may include providing a first die having a first sidewall on a substrate, providing a second die having a second sidewall different than the first sidewall of the first die on the substrate, and stitching the first die at the first sidewall to the second die at the second sidewall using a stitching reticle.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1 is a plan view (e.g., top view) of a solid state device according to one or more embodiments.

FIG. 2 illustrates a detailed plan view of region of the solid state device in FIG. 1 according to one or more embodiments.

FIG. 3A illustrates a vertical cross-sectional view of the first sidewall of the first die according to one or more embodiments.

FIG. 3B illustrates a vertical cross-sectional view of the second sidewall of the second die according to one or more embodiments.

FIG. 4 illustrates a vertical cross-sectional view along the line A-A′ in FIG. 2 according to one or more embodiments.

FIG. 5 illustrates a detailed plan view (e.g., top-down view) of the stitching region according to one or more embodiments.

FIG. 6A illustrates an intermediate structure including the first dies and second dies on the substrate according to one or more embodiments.

FIG. 6B illustrates an intermediate structure including a first reticle (stitching reticle) over the substrate according to one or more embodiments.

FIG. 6C illustrates the solid state device including the first stitching regions and the second stitching regions according to one or more embodiments.

FIG. 7 is a flow chart illustrating a method of forming the solid state device according to one or more embodiments.

### DETAILED DESCRIPTION

As discussed above, the embodiments of the present disclosure are directed to solid state devices, and particularly to a solid state device including a stitch portion between different dies, and methods of forming the same, the various aspects of which are discussed herein in detail. The drawings are not necessarily drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “layer” refers to a continuous portion of at least one material including a region having a thickness. A layer may consist of a single material portion having a homogeneous composition, or may include multiple material portions having different compositions.

As used herein, a “conductive material” refers to a material having electrical conductivity greater than 1.0×10⁻⁵ S/cm. As used herein, an “insulator material” or a “dielectric material” refers to a material having electrical conductivity less than 1.0×10⁻⁵ S/cm. As used herein, a “semiconducting material” refers to a material having electrical conductivity in the range from 1.0×10⁻⁵ S/cm to 1.0×10⁵ S/cm. As used herein, a “metallic material” refers to a conductive material including at least one metallic element therein. All measurements for electrical conductivities are made at the standard condition.

Stitching is a process that has been considered for forming chips (e.g., solid state dies, such as semiconductor (e.g., electronic) dies and photonic IC dies) larger than a typical reticle field (e.g., about 26×33 mm). Stitching is typically used to stitch together two chips having the same structure. That is, stitching is typically limited to cases where the same chip is being repeated across an entire wafer. In such cases, a stitching field (e.g., stitching region) may connect adjacent fields in the two chips having the same structure.

It may be desirable at times to co-integrate different technologies at a chip level. Integrating different chips with each other may typically done via a number of technologies including wafer-to-wafer bonding, chip-to-wafer bonding, chip-to-chip bonding or chip-to-interposer. Co-integration of different chips on a common substrate (e.g., silicon substrate) may be possible for smaller chips which are smaller than a full reticle, but difficult for full reticle chips. Additionally, different chips often benefit from differing patterning schemes at active layers.

An embodiment of the present disclosure may include a solid state device including two or more different solid state dies (chips) that are stitched together. This may allow the solid state device to co-integrate different technologies at a chip level. In at least one embodiment, a common structure in different dies may be used to facilitate stitching together the different solid state dies. The common structure may include, for example, a common inactive layer such as a back end of line (BEOL) structure (e.g., a wiring layer or conductive trace). The common inactive layer may alternatively or additionally include a middle of line (MOL) structure.

At least one embodiment may include a method of stitching together two or more different solid state dies located on the same substrate (e.g., wafer) using the same stitching reticle or reticles. In at least one embodiment multi-reticle systems may be stitched together at a common inactive (e.g., non-critical) layer. The method may be used, for example, to form integrated circuits (ICs) such as photonic ICs, electronic ICs, other types of ICs, or hybrid ICs, which are growing increasingly complex. For example, the different dies may include photonic solid state device IC dies and semiconductor device dies (e.g., control electronic dies for controlling the photonic IC dies) on the same substrate. The photonic IC dies may include interferometers and/or waveguides. The semiconductor device dies may include semiconductor (e.g., silicon) transistor based logic dies.

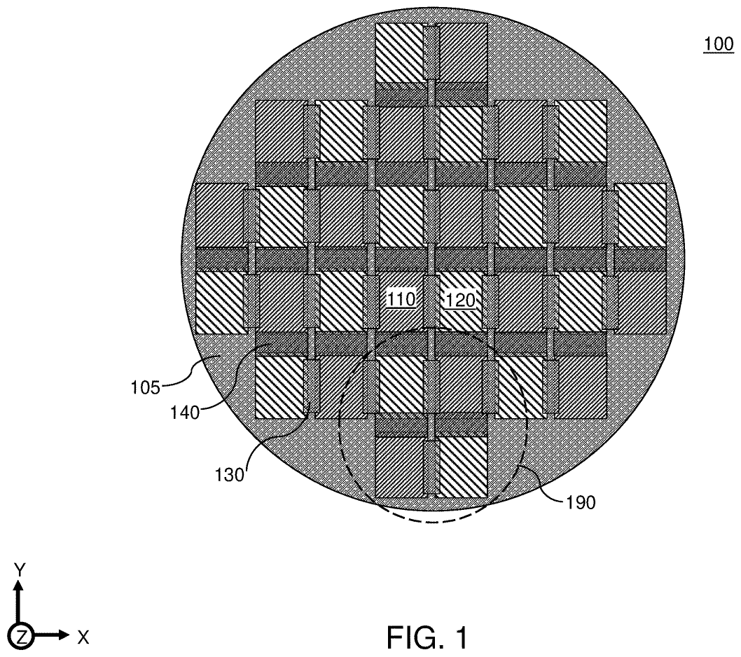

FIG. 1 is a plan view (e.g., top view) of a solid state device 100 according to one or more embodiments. As illustrated in FIG. 1, the solid state device 100 may include a substrate 105. The substrate 105 may include, for example, a semiconductor wafer (e.g., silicon wafer). The solid state device 100 may also include one or more first dies 110 (e.g., first primary dies, first die 110) and one or more second dies 120 (e.g., second primary dies, second die 120). The first dies 110 and the second dies 120 may be formed (e.g., grown layer by layer and patterned by a suitable patterning method, etc.) on the substrate 105.

The first dies 110 may have a first die type. The second dies 120 may have a second die type that is different than the first die type. Each of the first dies 110 and the second dies 120 may include, for example, a photonic IC die, an electronic IC die, a hybrid IC die (e.g., a die including both photonic and electronic elements), or another type of IC die.

The first dies 110 and second dies 120 may be organized on the substrate 105 into a regular array. In at least one embodiment, about half of the total dies (e.g., the total number of first dies 110 and second dies 120) in the solid state device 100 may include the first dies 110 and the other half may include the second dies 120. In at least one embodiment, the first dies 110 and the second dies 120 may be alternatingly formed in the x-direction and alternatingly formed in the y-direction. The solid state device 100 may include one or more first stitching regions 130 between a first die 110 and a second die 120 and extending longitudinally in the y-direction. The solid state device 100 may include one or more second stitching regions 140 between a first die 110 and a second die 120 and extending longitudinally in the x-direction.

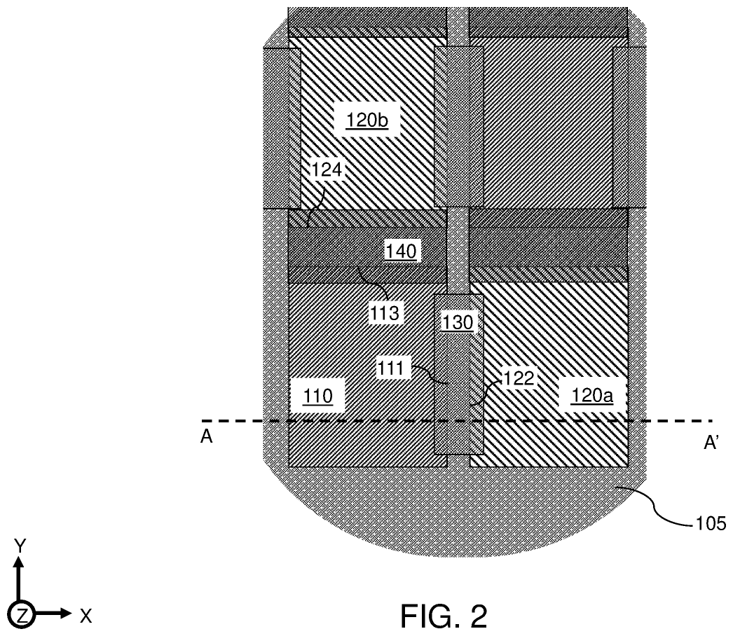

FIG. 2 illustrates a detailed plan view of region 190 of the solid state device 100 in FIG. 1 according to one or more embodiments. As illustrated in FIG. 2, the first die 110 may include a first sidewall 111 and the second die 120a may include a second sidewall 122. The first sidewall 111 of the first die 110 may face the second sidewall 122 of the second die 120a. A first stitching region 130 (e.g., horizontal stitching region) may be located between the first sidewall 111 of the first die 110 and the second sidewall 122 of the second die 120a. In addition, the first die 110 may include a third sidewall 113 and the second die 120b (e.g., third die) may include a fourth sidewall 124. The third sidewall 113 of the first die 110 may face the fourth sidewall 124 of the second die 120b. A second stitching region 140 (e.g., vertical stitching region) may be located between the third sidewall 113 of the first die 110 and the fourth sidewall 124 of the second die 120b.

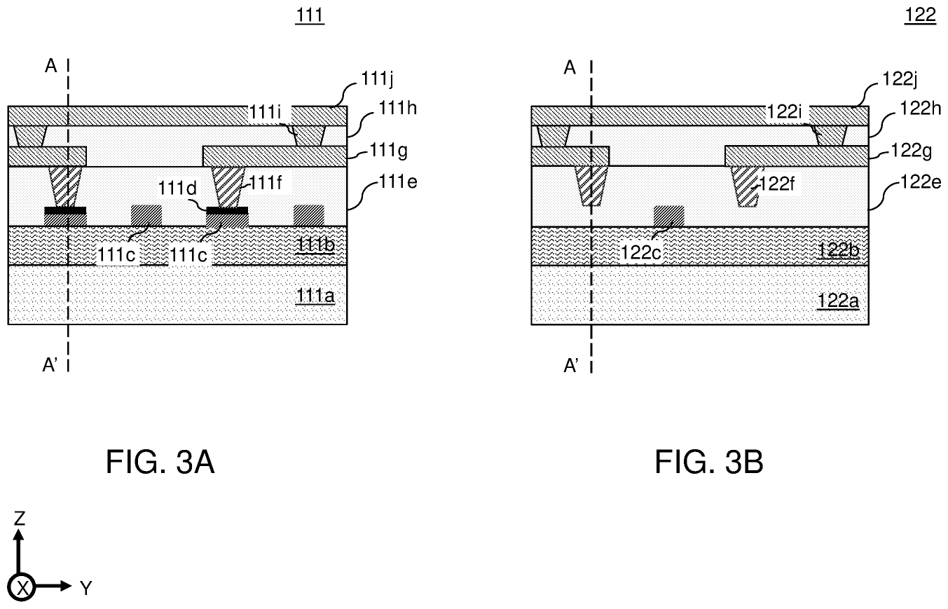

FIG. 3A illustrates a vertical cross-sectional view of the first sidewall 111 of the first die 110 according to one or more embodiments. As illustrated in FIG. 3A, at the first sidewall 111, the first die 110 may include a substrate layer 111a (e.g., silicon layer). An oxide layer 111b (e.g., buried oxide layer (BOX)) may be located on the substrate layer 111a. The oxide layer 111b may include, for example, silicon dioxide and may serve as a bottom cladding layer. One or more optical waveguides 111c (e.g., channel waveguide) may be located on the oxide layer 111b. The optical waveguides 111c may include, for example, a semiconductor material (e.g., silicon, germanium, etc.). Alternatively, the optical waveguides 111c may include an insulating material, such as silicon nitride instead of or in addition to the semiconductor material. An optional blocking layer 111d may be located on the optical waveguides 111c. The blocking layer 111d may include, for example, a silicide layer, such as nickel silicide. An upper cladding layer 111e (e.g., silicon dioxide) may be formed on the oxide layer 111b over the optical waveguides 111c and the blocking layer 111d. A conductive contact 111f may be formed in the upper cladding layer 111e and contact the blocking layer 111d. The conductive contact 111f may include a metal material such as tungsten. Other metals are within the contemplated scope of disclosure.

A first interconnect layer 111g (e.g., a metal layer or metal trace) may be formed on the upper cladding layer 111e. An interlayer dielectric layer (IDL) 111h may be formed on the first interconnect layer 111g. The IDL 111h may include silicon dioxide, although other dielectric materials are within the contemplated scope of disclosure. A second interconnect layer 111j (e.g., a metal layer or metal trace) may be formed on the IDL 111h and connected to the first interconnect layer 111g by a conductive via 111i (e.g., a metal via) formed in the IDL 111h. Each of the first interconnect layer 111g, conductive via 111i and second interconnect layer 111j may include copper or a copper alloy, although other metals and metal alloys are within the contemplated scope of disclosure.

FIG. 3B illustrates a vertical cross-sectional view of the second sidewall 122 of the second die 120 according to one or more embodiments. As illustrated in FIG. 3B, at the second sidewall 122, the second die 120 may have a structure that is substantially similar in some respects to the structure of the first sidewall 111 of the first die 110. In particular, at the second sidewall 122, the second die 120 may include a substrate layer 122a similar to the substrate layer 111a, an oxide layer 122b similar to the oxide layer 111b, an upper cladding layer 122e similar to upper cladding layer 111e, a conductive contact 122f similar to conductive contact 111f, a first interconnect layer 122g similar to first interconnect layer 111g, an IDL 122h similar to IDL 111h, a second interconnect layer 122j similar to second interconnect layer 111j, and a conductive via 122i similar to conductive via 111i.

As further illustrated in FIG. 3B, the second die 120 at the second sidewall 122 may have a structure that different in some respects from the structure of the first sidewall 111 of the first die 110. In particular, the optical waveguide 122c at the second sidewall 122 of the second die 120 may different and/or located in a different location than the optical waveguides 111c at the first sidewall 111 of the first die 110. In addition, the second sidewall 122 of the second die 120 may not include a blocking layer corresponding to the blocking layer 111d in the first sidewall 111 of the first die 110.

Thus, a configuration (e.g., structure) of the first sidewall 111 of the first die 110 may be dissimilar to a configuration of the second sidewall 122 of the second die 120. However, there is at least one inactive (e.g., non-critical) layer that is common to both the first sidewall 111 and the second sidewall 122. For example, inactive BEOL layers, such as the first interconnect layer 111g and first interconnect layer 122g, the conductive via 111i and the conductive via 122i, and second interconnect layer 111j and second interconnect layer 122j, are common to both the first sidewall 111 and the second sidewall 122. In another example, inactive (e.g., non-critical) MOL layers, such as the conductive contacts 111f and the conductive contacts 122f, are common to both the first sidewall 111 and the second sidewall 122. Additionally, other non-critical layers, such as waveguide 111e and waveguide 122c may be common to both the first sidewall 111 and the second sidewall 122. Stitching can occur between one or more of first interconnect layer 111g and first interconnect layer 122g, the second interconnect layer 111j and second interconnect layer 122j, or the optical waveguide 111c and optical waveguide 122c.

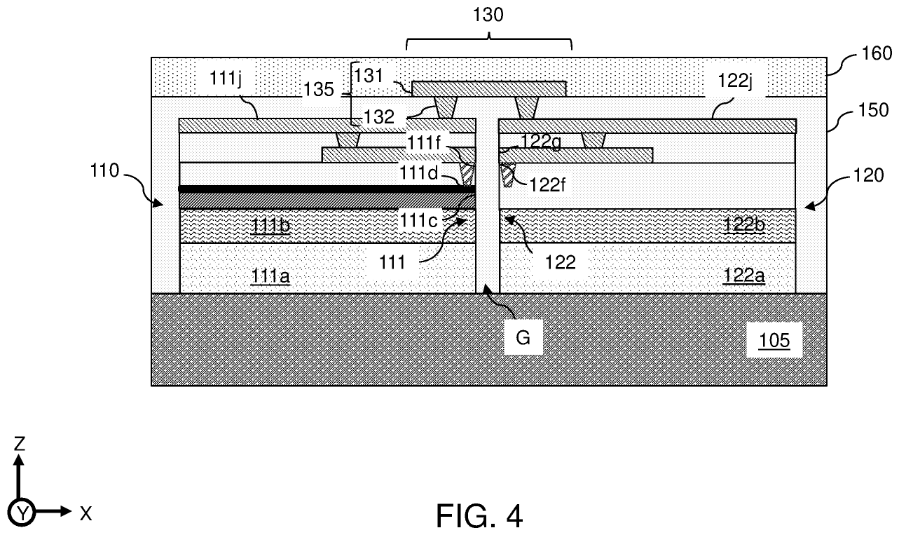

FIG. 4 illustrates a vertical cross-sectional view along the line A-A′ in FIG. 2 according to one or more embodiments. The line A-A′ with respect to the first die 110 and the second die 120 is also illustrated FIGS. 3A and 3B, respectively.

As illustrated in FIG. 4, the second die 120 may be located on the substrate 105 adjacent to the first die 110. In particular, the first sidewall 111 of the first die 110 may face the second sidewall 122 of the second die 120, with a gap G formed between the first sidewall 111 and the second sidewall 122. A dielectric encapsulation layer 150 (e.g., silicon dioxide) may be formed on the first die 110 and second die 120 and in the gap G.

As further illustrated in FIG. 4, the first stitching region 130 may include the first sidewall 111 of the first die 110, the gap G, and the second sidewall 122 of the second die 120. The first stitching region 130 may further include a stitching layer 131 on the dielectric encapsulation layer 150. The stitching layer 131 may extend across the gap G in the x-direction. The first stitching region 130 may also include a stitching via 132 in the encapsulation layer 150 and connecting the stitching layer 131 to the second interconnect layer 111j (first non-critical layer) in the first die 110, and a stitching via 132 in the encapsulation layer 150 and connecting the stitching layer 131 to the second interconnect layer 122j (second non-critical layer) in the second die 120. The stitching layer 131 and the stitching vias 132 may together constitute a stitching structure 135 (first stitch portion). Each of the stitching layer 131 and the stitching vias 132 may include copper or a copper alloy, although other conductive materials, such as metals and metal alloys are within the contemplated scope of disclosure. An upper dielectric layer 160 (e.g., silicon dioxide) may be formed on the encapsulation layer 150 and on the stitching layer 131. Optionally, the respective waveguides 111c and 122c may also be stitched together across the respective first and second die.

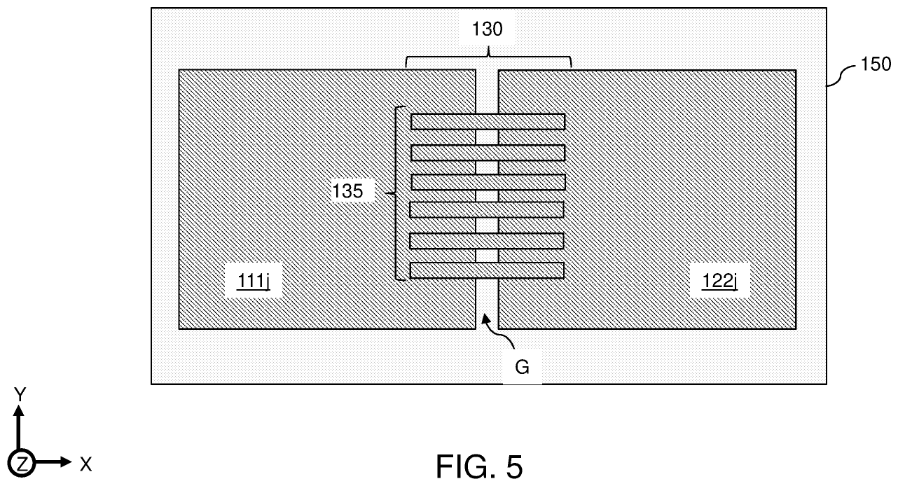

FIG. 5 illustrates a detailed plan view (e.g., top-down view) of the stitching region 130 according to one or more embodiments. The upper dielectric layer 160 has been omitted from FIG. 5 for ease of explanation. As illustrated in FIG. 5, the stitching region 130 may include a plurality of stitching structures 135. In particular, the plurality of stitching structures 135 may be formed along the length of the stitching region 130 in the y-direction.

It should also be noted that the second stitching region 140 in FIGS. 1 and 2 may have a configuration that is substantially similar to the configuration of the first stitching region 130. In particular, the second stitching region 140 may include a plurality of stitching structures (second stitch portions) that are substantially similar to the stitching structures 135.

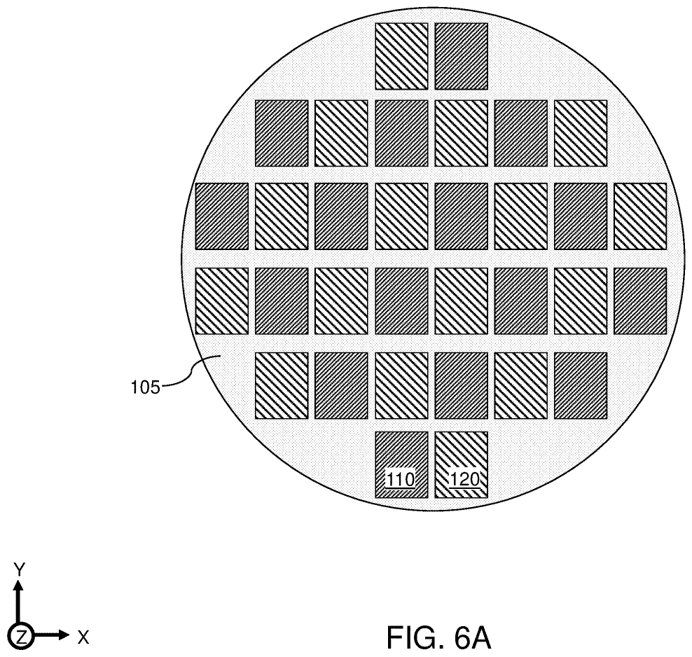

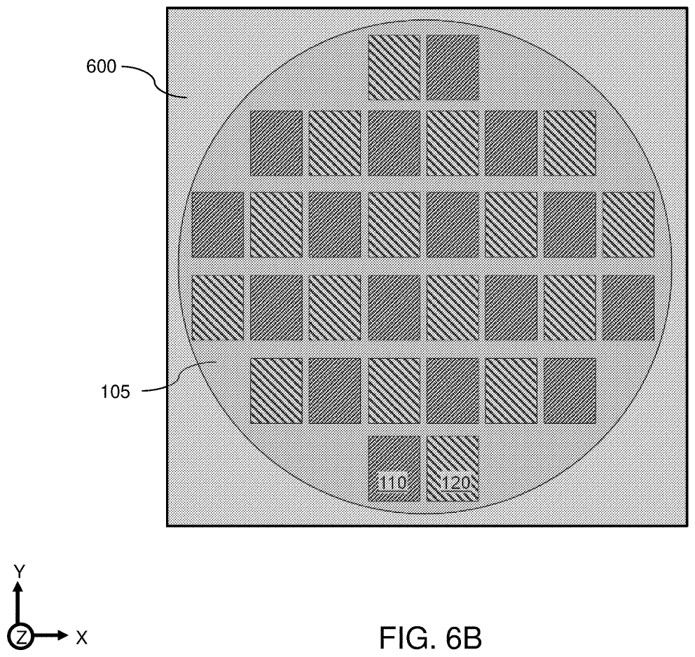

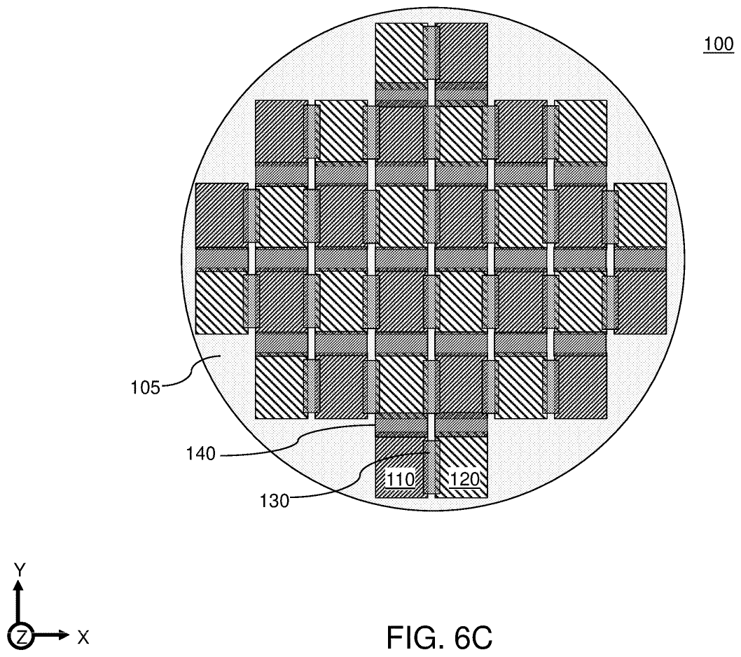

FIGS. 6A-6C illustrate a method of forming the solid state device 100 according to one or more embodiments. In particular, FIG. 6A illustrates an intermediate structure including the first dies 110 and second dies 120 on the substrate 105 according to one or more embodiments.

As illustrated in FIG. 6A, the first dies 110 may be aligned in the x-direction with second dies 120 and also aligned in the y-direction with second dies 120, so as to form a regular array on the substrate 105. In other words, the first dies 110 may alternate with the second dies 120 in both the x-direction and the y-direction. In particular, the first dies 110 and second dies 120 may be aligned on the substrate 105 so that the common inactive (e.g. non-critical) layer at a first sidewall 111 of the first die 110 may therefore be substantially aligned with the common inactive (e.g., non-critical) layer at the second sidewall 122 of the second die 120. The encapsulation layer 150 (see FIG. 4) may then be formed on the first dies 110 and second dies 120.

FIG. 6B illustrates an intermediate structure including a first reticle 600 (stitching reticle) located over the substrate 105 according to one or more embodiments. While the stitching reticle 600 is shown as covering the area entire substrate 105, it should be noted that the stitching reticle 600 may have an area smaller than the entire substrate 105, and be moved in the x and/or y directions above the substrate 105 during exposure. A photoresist layer (not shown) may be formed on the encapsulation layer 150, and over the first dies 110 and the second dies 120. The photoresist layer may then be patterned using the first reticle 600 as a mask. The first reticle 600 may be used to expose a photoresist layer for forming the first stitching region 130 and/or the second stitching region 140. The exposed photoresist layer is then developed to form a patterned photoresist layer. An etching step may then be performed in order to etch the encapsulation layer 150 so as to form via openings for the stitching vias 132 using the patterned photoresist layer as a mask. The first dies 110 and second dies 120 may also be etched at this point as needed to form the stitching structures 135 (see FIGS. 4 and 5). A metal layer (e.g., copper layer) may then be formed on the encapsulation layer 150 and in the via openings, so as to form the stitching vias 132. The metal layer may then be patterned by a photolithographic process so as to form the stitching layer 131. The upper dielectric layer 160 may then be formed on the encapsulation layer 150 and the stitching layer 131.

It should be noted that in the forming of the first stitching region 130 and/or second stitching region 140, the same photoresist layer may be exposed sequentially in one or more first stitching regions 130 and/or second stitching regions 140. Further, another photoresist layer used in patterning of the active (e.g., critical) layers in the first dies 110 and the second dies 120 may be exposed simultaneously in all of the first dies 110 and the second dies 120, or may be expose sequentially in one or more of the first dies 110 and the second dies 120. Furthermore, a plurality of the inactive (e.g., non-critical) layers in the first dies 110 and the second dies 120 may be formed using the same or similar process steps. Each of the first dies 110 and the second dies 120 may have unique designs at active (e.g., critical) layers and can have unique mask patterns and lithographic exposure conditions for the active layers.

Further, each of the first dies 110 may be stitched to the one or more second dies 120 using the reticle 600. In particular, the same reticle 600 (e.g., the same horizontal and/or vertical stitching reticle) may be used to form the first stitching regions 130 and second stitching regions 140 at the interfaces between the first dies 110 and second dies 120 (e.g., at the chip interfaces). In at least one embodiment, a small number of new masks (e.g., about 2-5 new masks) for each reticle may be used to form the active layers in the respective dies. However, it may be unnecessary to use a full additional mask set which may require up to 30 masks or more. In at least one embodiment, one or more first dies 110 may be stitched to the one or more second dies 120 using the same horizontal and/or vertical stitching reticle at the interfaces between the first dies 110 and second dies 120 (e.g., at the chip interfaces).

FIG. 6C illustrates the solid state device 100 including the first stitching regions 130 and the second stitching regions 140 according to one or more embodiments. As illustrated in FIG. 6C, the solid state device 100 may include the first stitching regions 130 and the second stitching regions 140 that may be formed by the reticle 600.

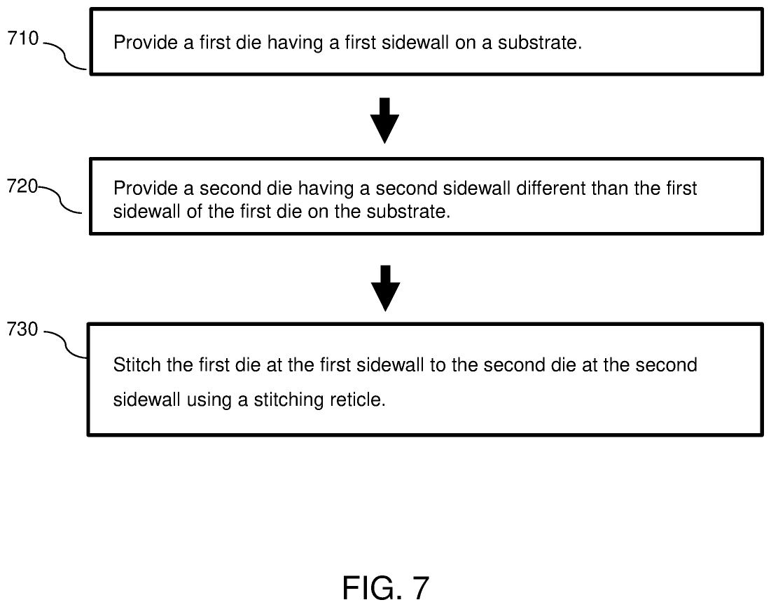

FIG. 7 is a flow chart illustrating a method of forming the solid state device 100 according to one or more embodiments. Step 710 includes providing a first die having a first sidewall on a substrate. Step 720 includes providing a second die having a second sidewall different than the first sidewall of the first die on the substrate. Step 730 includes stitching the first die at the first sidewall to the second die at the second sidewall using a stitching reticle.

The solid state device 100 and method of forming the solid state device may provide several improvements over typical devices and methods. In particular, the solid state device 100 may provide a multi-exposure, multi-reticle wafer with more than one chip design on the wafer that may be subsequently stitched at one or more levels. The chips (e.g., first die 110 and second die 120) may have common designs on non-critical levels to reduce mask counts. Further, different mask fabrication technologies may be leveraged to suit specific needs on each chip (e.g., first die 110 and second die 120). Different lithographic exposure conditions may be used for each chip in order to optimize each chip (e.g., first die 110 and second die 120). Further, a common photoresist layer with multiple exposures of different reticles may be used to stitch the different chips (e.g., first die 110 and second die 120).

The solid state device 100 and method of forming the solid state device may provide several advantages over typical devices. In particular, monolithically integrated and stitched wafer level integration of different chips (e.g., first die 110 and second die 120) may provide low loss optics and low resistance electrical connectivity. Each of the chips (e.g., first die 110 and second die 120) can use the full reticle field. Each of the chips (e.g., first die 110 and second die 120) can have mask fabrication and lithography exposure optimized for unique requirements. Further, common non-critical layers (e.g., MOL and BEOL) may mean that mask count is not proportionate to the number of dies, so that processing costs may be kept low.

The following are examples:

Example 1. A solid state device, comprising: a substrate; a first die on the substrate and having a first sidewall; a second die different than the first die on the substrate and having a second sidewall facing the first sidewall; and a first stitch portion connecting the first die at the first sidewall to the second die at the second sidewall.

Example 2. The solid state device of as example 1 describes, wherein the first die has a first configuration at the first sidewall, and the second die has a second configuration different than the first configuration at the second sidewall.

Example 3. The solid state device of as either of examples 1 or 2 describe, wherein the first die includes a first inactive layer at the first sidewall, the second die includes a second inactive layer at the second sidewall that is substantially the same as the first inactive layer, and the first stitch portion stitches the first inactive layer to the second inactive layer.

Example 4. The solid state device of as any of examples 1-3 describe, wherein the first die includes a first active layer that is not included in the second die.

Example 5. The solid state device of as any of examples 1-4 describe, wherein the first die further comprises a third sidewall that is substantially perpendicular to the first sidewall.

Example 6. The solid state device of as any of examples 1-5 describe, further comprising: a third die on the substrate and having a fourth sidewall facing the third sidewall of the first die; and a second stitch portion connecting the first die at the third sidewall to the third die at the fourth sidewall.

Example 7. The solid state device of as any of examples 1-6 describe, wherein each of the first die and the second die comprise one of a photonic integrated circuit (IC) die, an electronic IC die or a hybrid photonic and electronic IC die.

Example 8. The solid state device of as any of examples 1-7 describe, wherein the first die comprises the photonic IC die containing a waveguide.

Example 9. The solid state device of as any of examples 1-8 describe, wherein the substrate comprises a silicon wafer.

Example 10. The solid state device of as any of examples 1-9 describe, wherein: the first die contains a first inactive layer at the first sidewall; the second die includes a second inactive layer at the second sidewall; a gap is located between the first sidewall and the second sidewall; an encapsulation layer located on the first die and the second die and in the gap; and the first stitch portion comprises at least one conductive stitching structure located on the encapsulation layer and extending over the gap so as to connect the first inactive layer of the first die to the second inactive layer of the second die.

Example 11. A method of forming a solid state device, comprising: providing a first die having a first sidewall on a substrate; providing a second die having a second sidewall different than the first sidewall of the first die on the substrate; and stitching the first die at the first sidewall to the second die at the second sidewall using a stitching reticle.

Example 12. The method of as example 11 describes, wherein the first die has a third sidewall substantially perpendicular to the first sidewall, and the method further comprises: providing a third die having a fourth sidewall on the substrate; and stitching the first die at the third sidewall to the third die at the fourth sidewall using the stitching reticle.

Example 13. The method of as either of examples 11 or 12 describe, wherein the stitching of the first die to the second die comprises forming a first stitching region between the first die and the second die, and the stitching of the first die to the third die comprises forming a second stitching region between the first die and the third die.

Example 14. The method of as any of examples 11-13 describe, wherein the stitching of the first die to the second die comprises stitching the first die to the second die at a plurality of levels.

Example 15. The method of as any of examples 11-14 describe, wherein a configuration of the first sidewall of the first die at an inactive level is substantially the same as a configuration of the second sidewall of the second die at an inactive level.

Example 16. The method of as any of examples 11-15 describe, wherein the stitching of the first die to the second die comprises exposing a photoresist layer using the stitching reticle and developing the exposed photoresist layer to form a patterned photoresist layer, and etching at least one layer located in a stitching region between the first die and the second die using the patterned photoresist layer as a mask.

Example 17. The method of as any of examples 11-16 describe, wherein each of the first die and the second die comprise one of a photonic integrated circuit (IC) die, an electronic IC die or a hybrid photonic and electronic IC die.

Example 18. The method of as any of examples 11-17 describe, wherein the first die comprises the photonic IC die containing a waveguide.

Example 19. The method of as any of examples 11-18 describe, wherein the substrate comprises a silicon wafer.

Example 20. The method of as any of examples 11-19 describe, wherein: the first die contains a first inactive layer at the first sidewall; the second die includes a second inactive layer at the second sidewall; a gap is located between the first sidewall and the second sidewall; an encapsulation layer is formed on the first die and the second die and in the gap; and the stitching the first die at the first sidewall to the second die at the second sidewall using the stitching reticle comprises using the stitching reticle during exposure of a photoresist layer located over the first die, the second die and the gap.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A solid state device, comprising:
a substrate;
a first die on the substrate and having a first sidewall;
a second die different than the first die on the substrate and having a second sidewall facing the first sidewall; and
a first stitch portion connecting the first die at the first sidewall to the second die at the second sidewall.

2. The solid state device of claim 1, wherein the first die has a first configuration at the first sidewall, and the second die has a second configuration different than the first configuration at the second sidewall.

3. The solid state device of claim 2, wherein the first die includes a first inactive layer at the first sidewall, the second die includes a second inactive layer at the second sidewall that is substantially the same as the first inactive layer, and the first stitch portion stitches the first inactive layer to the second inactive layer.

4. The solid state device of claim 3, wherein the first die includes a first active layer that is not included in the second die.

5. The solid state device of claim 1, wherein the first die further comprises a third sidewall that is substantially perpendicular to the first sidewall.

6. The solid state device of claim 5, further comprising:
a third die on the substrate and having a fourth sidewall facing the third sidewall of the first die; and
a second stitch portion connecting the first die at the third sidewall to the third die at the fourth sidewall.

7. The solid state device of claim 1, wherein each of the first die and the second die comprise one of a photonic integrated circuit (IC) die, an electronic IC die or a hybrid photonic and electronic IC die.

8. The solid state device of claim 7, wherein the first die comprises the photonic IC die containing a waveguide.

9. The solid state device of claim 1, wherein the substrate comprises a silicon wafer.

10. The solid state device of claim 1, wherein:
the first die contains a first inactive layer at the first sidewall;
the second die includes a second inactive layer at the second sidewall;
a gap is located between the first sidewall and the second sidewall;
an encapsulation layer located on the first die and the second die and in the gap; and
the first stitch portion comprises at least one conductive stitching structure located on the encapsulation layer and extending over the gap so as to connect the first inactive layer of the first die to the second inactive layer of the second die.

11. A method of forming a solid state device, comprising:
providing a first die having a first sidewall on a substrate;
providing a second die having a second sidewall different than the first sidewall of the first die on the substrate; and
stitching the first die at the first sidewall to the second die at the second sidewall using a stitching reticle.

12. The method of claim 11, wherein the first die has a third sidewall substantially perpendicular to the first sidewall, and the method further comprises:
providing a third die having a fourth sidewall on the substrate; and
stitching the first die at the third sidewall to the third die at the fourth sidewall using the stitching reticle.

13. The method of claim 12, wherein the stitching of the first die to the second die comprises forming a first stitching region between the first die and the second die, and the stitching of the first die to the third die comprises forming a second stitching region between the first die and the third die.

14. The method of claim 11, wherein the stitching of the first die to the second die comprises stitching the first die to the second die at a plurality of levels.

15. The method of claim 11, wherein a configuration of the first sidewall of the first die at an inactive level is substantially the same as a configuration of the second sidewall of the second die at an inactive level.

16. The method of claim 11, wherein the stitching of the first die to the second die comprises exposing a photoresist layer using the stitching reticle and developing the exposed photoresist layer to form a patterned photoresist layer, and etching at least one layer located in a stitching region between the first die and the second die using the patterned photoresist layer as a mask.

17. The method of claim 11, wherein each of the first die and the second die comprise one of a photonic integrated circuit (IC) die, an electronic IC die or a hybrid photonic and electronic IC die.

18. The method of claim 17, wherein the first die comprises the photonic IC die containing a waveguide.

19. The method of claim 11, wherein the substrate comprises a silicon wafer.

20. The method of claim 11, wherein:
the first die contains a first inactive layer at the first sidewall;
the second die includes a second inactive layer at the second sidewall;
a gap is located between the first sidewall and the second sidewall;
an encapsulation layer is formed on the first die and the second die and in the gap; and
the stitching the first die at the first sidewall to the second die at the second sidewall using the stitching reticle comprises using the stitching reticle during exposure of a photoresist layer located over the first die, the second die and the gap.
